(19) United States
(12) Patent Application Publication
(10) Pub. No.: US 2020/0410149 A1
(43) Pub. Date: Dec. 31, 2020

(54) HIGH-LEVEL SYNTHESIS APPARATUS, HIGH-LEVEL SYNTHESIS METHOD, AND COMPUTER READABLE MEDIUM

(71) Applicant: MITSUBISHI ELECTRIC CORPORATION, Tokyo (JP)

(72) Inventor: Ryo YAMAMOTO, Tokyo (JP)

(73) Assignee: MITSUBISHI ELECTRIC CORPORATION, Tokyo (JP)

(21) Appl. No.: 16/978,968

(22) PCT Filed: Mar. 26, 2018
(86) PCT No.: PCT/JP2018/011999

§ 371 Date: Sep. 8, 2020

(51) Int. Cl. G06F 30/327; G06F 30/33; G06F 30/34

(52) U.S. Cl. CPC G06F 30/327; G06F 30/34; G06F 30/33

(57) ABSTRACT

A high-level synthesis apparatus (100) performs a high-level synthesis process on a behavioral description that describes operation of a circuit, and outputs hardware description language that causes the circuit to operate. A data hazard detection unit (150) detects, as a data hazard portion, a portion of the behavioral description in which a data hazard has occurred. A workaround determination unit (170) determines a workaround to resolve the data hazard in the data hazard portion based on estimated performance values (610) which are estimated values of circuit performance including latency and circuit scale of the circuit. The workaround determination unit (170) determines, as the workaround, one of a method of reducing pipeline performance of the circuit, a method of reducing operating frequency of the data hazard portion, and a method composed of a combination of the method of reducing the pipeline performance of the circuit and the method of reducing the operating frequency of the data hazard portion.

### TECHNICAL FIELD

The present invention relates to a high-level synthesis apparatus, a high-level synthesis method, and a high-level synthesis program. In particular, the present invention relates to a high-level synthesis apparatus, a high-level synthesis method, and a high-level synthesis program for supporting semiconductor designing using high-level synthesis or behavioral synthesis.

### BACKGROUND ART

High-level synthesis or behavioral synthesis is a technology to automatically generate hardware description language such as register transfer level (RTL) from a behavioral description.

In conventional designing of semiconductor integrated circuits, a hardware description language is used to describe operation of circuits that combine registers with flip-flops. In recent years, the circuit scale of integrated circuits is increasing, and a great deal of design time is required for designing using a hardware description language. Therefore, there is provided a technology to perform designing using a high-level language, such as the C language, the C++ language, the SystemC language, or the Matlab language, having a higher abstraction level than hardware description languages, and to automatically generate RTL. Tools to realize this technology are commercially available as high-level synthesis tools.

A designer designs a circuit by inputting source code using a high-level language and circuit specifications into a high-level synthesis tool. For circuit specifications that cannot be expressed in a high-level language or cannot be efficiently expressed by source code, the designer sets high-level synthesis options, such as options, attributes, or pragmas, and inputs them into the high-level synthesis tool.

The high-level synthesis options are selected in order to design a circuit that meets non-functional requirements such as latency and circuit scale. The high-level synthesis options such as a circuit architecture, buffer insertion, or pipeline specifications need to be selected by the designer. Thus, the designer still has much work to do, and there is room for improvement in terms of design efficiency.

Therefore, in Patent Literature 1, design efficiency is improved by automatically determining a circuit architecture based on non-functional requirements and then performing high-level synthesis.

### CITATION LIST

### Patent Literature

Patent Literature 1: WO 2017/154183 A1

### SUMMARY OF INVENTION

### Technical Problem

In Patent Literature 1, high-level synthesis is performed by specifying pipelining for a circuit. However, pipelining may not be possible due to a data hazard. There are two types of workarounds when pipelining is not possible due to a data hazard. However, Patent Literature 1 does not disclose these workarounds, and if high-level synthesis cannot be performed with the determined architecture, the circuit will not be synthesized correctly.

The present invention provides a high-level synthesis apparatus that can automatically obtain an optimal workaround when a data hazard has occurred.

### Solution to Problem

A high-level synthesis apparatus according to the present invention performs a high-level synthesis process on a behavioral description that describes operation of a circuit, and outputs hardware description language that causes the circuit to operate, and the high-level synthesis apparatus includes

a data hazard detection unit to detect, as a data hazard portion, a portion of the behavioral description in which a data hazard has occurred; and

a workaround determination unit to determine, as a workaround to resolve the data hazard in the data hazard portion, one of a method of reducing pipeline performance of the circuit, a method of reducing operating frequency of the data hazard portion, and a method composed of a combination of the method of reducing the pipeline performance of the circuit and the method of reducing the operating frequency of the data hazard portion, based on latency and circuit scale of the circuit.

### Advantageous Effects of Invention

A high-level synthesis apparatus according to the present invention can obtain an optimal workaround when a data hazard has occurred.

### BRIEF DESCRIPTION OF DRAWINGS

FIG. 1 is a diagram describing occurrence of a data hazard;

FIG. 2 is an example of a timing chart when processing is performed once in every two cycles;

FIG. 3 is an example of a timing chart when synthesis is performed with reduced operating frequency;

FIG. 4 is a configuration diagram of a high-level synthesis apparatus according to a first embodiment;

FIG. 5 is a diagram illustrating input and output of the high-level synthesis apparatus according to the first embodiment;

FIG. 6 is a flowchart of a high-level synthesis process by the high-level synthesis process according to the first embodiment;

FIG. 7 is a sample example of source code according to the first embodiment;

FIG. 8 is a diagram illustrating latency and circuit scale of each function obtained from the sample example of source code in FIG. 7;

FIG. 9 is an example of a circuit configuration of a serial type;

FIG. 10 is an example of a circuit configuration of a parallel type;

FIG. 11 is a diagram illustrating an example of the flow of processing of the serial type on a time axis;

FIG. 12 is a diagram illustrating an example of the flow of processing of the parallel type on a time axis;

FIG. 13 is an example of first performance when DII is varied;

FIG. 14 is an example of second performance when frequency is reduced;

FIG. 15 is a flowchart in a case in which a function of calculating circuit performance by varying DII and a high-level synthesis unit are coordinated;

FIG. 16 is a flowchart of a case in which a function of calculating circuit performance by reducing operating frequency and the high-level synthesis unit are coordinated;

FIG. 17 is an example of first overall circuit performance when DII=2;

FIG. 18 is an example of first overall circuit performance when DII=3;

FIG. 19 is an example of second overall circuit performance when frequency is reduced;

FIG. 20 is a flowchart of a workaround determination process when a parallel type is input;

FIG. 21 is an example of first overall circuit performance when DII is varied in a case in which a F₃ function is a function in which a data hazard has occurred;

FIG. 22 is an example of second overall circuit performance when frequency is reduced in the case in which the F₃ function is the function in which the data hazard has occurred; and

FIG. 23 is a configuration diagram of the high-level synthesis apparatus according to a variation of the first embodiment.

### DESCRIPTION OF EMBODIMENTS

An embodiment of the present invention will be described hereinafter with reference to the drawings. Throughout the drawings, the same or corresponding portions are denoted by the same reference signs. In the description of the embodiment, description of the same or corresponding portions will be omitted or simplified as appropriate.

### First Embodiment

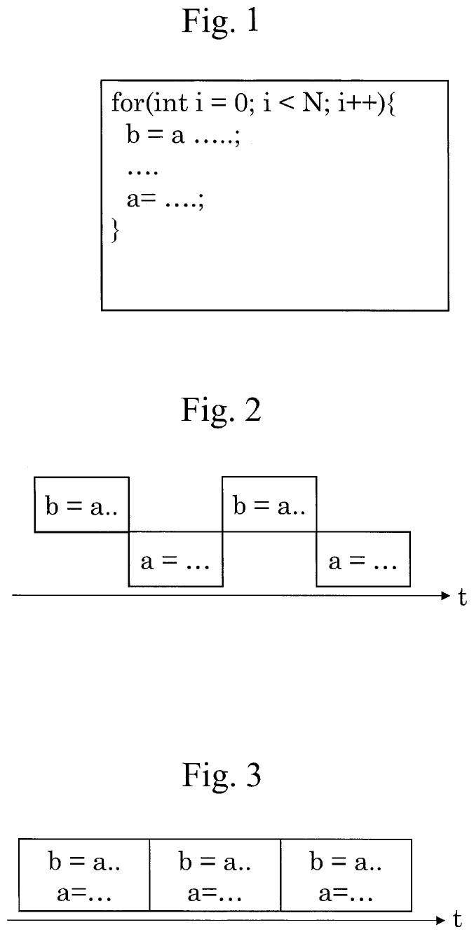

FIGS. 1 to 3 are diagrams describing occurrence of a data hazard.

Referring to FIG. 1, a data hazard and workarounds for occurrence of a data hazard will be described. As illustrated in FIG. 1, a data hazard is a type of pipeline hazard that may occur when there is logic that must be assigned to a variable after the variable is referred to. In FIG. 1, a variable named a does not allow pipelining unless the assignment to a has been completed at the next iteration.

Generally, there are two workarounds for a data hazard.

The first one is a method of reducing pipeline performance of a circuit. That is, pipeline synthesis is instructed so that processing is performed once in every two cycles. Note here that performing processing once in every cycle is referred to as DII (Data Initiation Interval)=1. DII is also referred to as II. Performing processing once in every two cycles is referred to as DII=2. DII=2 causes the performance to be halved when compared with DII=1. If the data hazard cannot be resolved even with DII=2, DII may be increased further. DII is an example of the number of cycles.

The method of reducing the pipeline performance of the circuit is a method of increasing the number of cycles for processing a data hazard portion in a behavioral description once.

The second one is a method of reducing operating frequency of the data hazard portion. That is, synthesis is performed at the reduced operating frequency. Since synthesis is performed at the reduced operating frequency, the target frequency is not achieved and thus the performance of the circuit deteriorates. The operating frequency is reduced until the data hazard is resolved. In other words, the operating frequency becomes such that the variable causing the data hazard can be processed in the next cycle, that is, in one cycle.

FIG. 2 illustrates an example of a timing chart when processing is performed once in every two cycles. FIG. 3 illustrates an example of a timing chart when synthesis is performed at the reduced operating frequency.

As described above, there are two types of workarounds for occurrence of a data hazard.

*** Description of Configuration ***

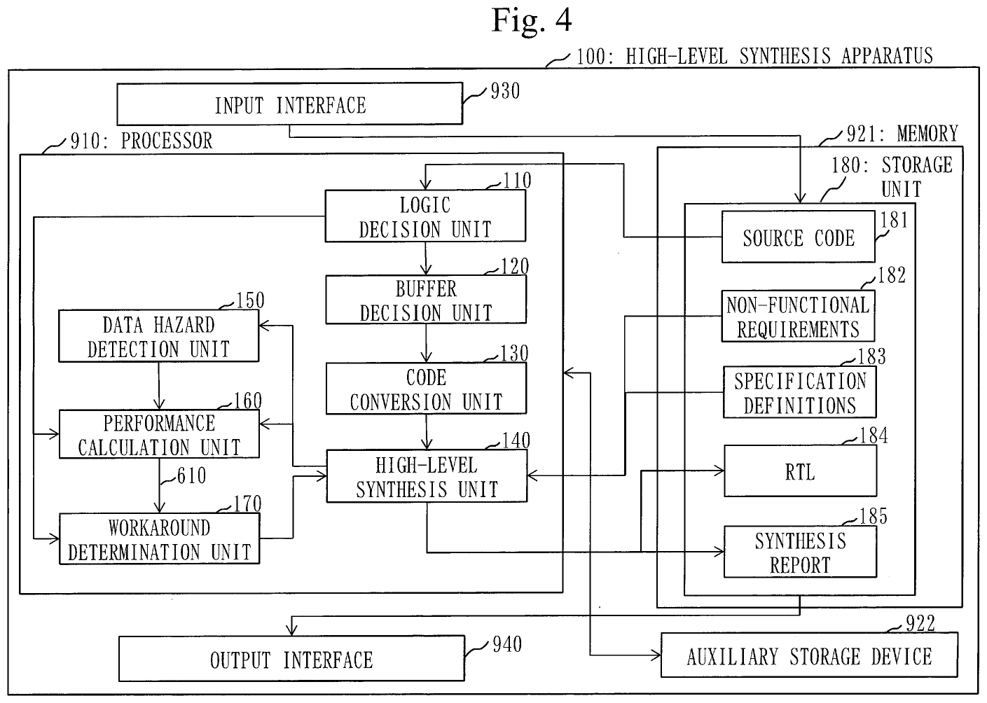

Referring to FIG. 4, a configuration of a high-level synthesis apparatus 100 according to this embodiment will be described.

The high-level synthesis apparatus 100 is a computer. The high-level synthesis apparatus 100 includes a processor 910, and also includes other hardware components such as a memory 921, an auxiliary storage device 922, an input interface 930, and an output interface 940. The processor 910 is connected with the other hardware components via signal lines and controls the other hardware components.

The high-level synthesis apparatus 100 includes, as functional elements, a logic decision unit 110, a buffer decision unit 120, a code conversion unit 130, a high-level synthesis unit 140, a data hazard detection unit 150, a performance calculation unit 160, a workaround determination unit 170, and a storage unit 180. The storage unit 180 stores source code 181, non-functional requirements 182, specification definitions 183, RTL 184, and a synthesis report 185.

The functions of the logic decision unit 110, the buffer decision unit 120, the code conversion unit 130, the high-level synthesis unit 140, the data hazard detection unit 150, the performance calculation unit 160, and the workaround determination unit 170 are realized by software. The storage unit 180 is included in the memory 921.

The processor 910 is a device that executes a high-level synthesis program. The high-level synthesis program is a program for realizing the functions of the logic decision unit 110, the buffer decision unit 120, the code conversion unit 130, the high-level synthesis unit 140, the data hazard detection unit 150, the performance calculation unit 160, and the workaround determination unit 170.

The processor 910 is an integrated circuit (IC) that performs arithmetic processing. Specific examples of the processor 910 area digital signal processor (DSP) and a graphics processing unit (GPU).

The memory 921 is a storage device to temporarily store data. Specific examples of the memory 921 are a static random access memory (SRAM) and a dynamic random access memory (DRAM) The auxiliary storage device 922 is a storage device to store data. A specific example of the auxiliary storage device 922 is an HDD. Alternatively, the auxiliary storage device 922 may be a portable storage medium such as an SD (registered trademark) memory card, CF, a NAND flash, a flexible disk, an optical disc, a compact disc, a Blu-ray (registered trademark) disc, or a DVD. HDD is an abbreviation for Hard Disk Drive. SD (registered trademark) is an abbreviation for Secure Digital. CF is an abbreviation for CompactFlash (registered trademark). DVD is an abbreviation for Digital Versatile Disk.

The input interface 930 is a port to be connected with an input device such as a mouse, a keyboard, or a touch panel. Specifically, the input interface 930 is a Universal Serial Bus (USB) terminal. The input interface 930 may be a port to be connected with a local area network (LAN).

The output interface 940 is a port to which a cable of an output device such as a display is to be connected. Specifically, the output interface 940 is a USB terminal or a High Definition Multimedia Interface (HDMI, registered trademark) terminal. Specifically, the display is a liquid crystal display (LCD).

The high-level synthesis program is read by the processor 910 and executed by the processor 910. The memory 921 stores not only the high-level synthesis program but also an operating system (OS). The processor 910 executes the high-level synthesis program while executing the OS. The high-level synthesis program and the OS may be stored in the auxiliary storage device 922. The high-level synthesis program and the OS stored in the auxiliary storage device 922 are loaded into the memory 921 and executed by the processor 910. Note that part or the entirety of the high-level synthesis program may be embedded in the OS.

The high-level synthesis apparatus 100 may include a plurality of processors as an alternative to the processor 910. These processors share the execution of the high-level synthesis program. Each of the processors is, like the processor 910, a device that executes the high-level synthesis program.

Data, information, signal values, and variable values that are used, processed, or output by the high-level synthesis program are stored in the memory 921 or the auxiliary storage device 922, or stored in a register or a cache memory in the processor 910.

The “unit” of each of the logic decision unit 110, the buffer decision unit 120, the code conversion unit 130, the high-level synthesis unit 140, the data hazard detection unit 150, the performance calculation unit 160, and the workaround determination unit 170 may be interpreted as a “process”, “procedure”, or “step”. The “process” of each of the logic decision process, the buffer decision process, the code conversion process, the high-level synthesis process, the data hazard process, the performance calculation process, and the workaround determination process may be interpreted as a “program”, “program product”, or “computer readable storage medium storing a program”.

The high-level synthesis program causes a computer to execute each process, each procedure, or each step, where the “unit” of each of the above units is interpreted as the “process”, “procedure”, or “step”. A high-level synthesis method is a method performed by the execution of the high-level synthesis program by the high-level synthesis apparatus.

The high-level synthesis program may be stored and provided in a computer readable recording medium. Alternatively, the high-level synthesis program may be provided as a program product.

<Input and Output of High-Level Synthesis Apparatus 100>

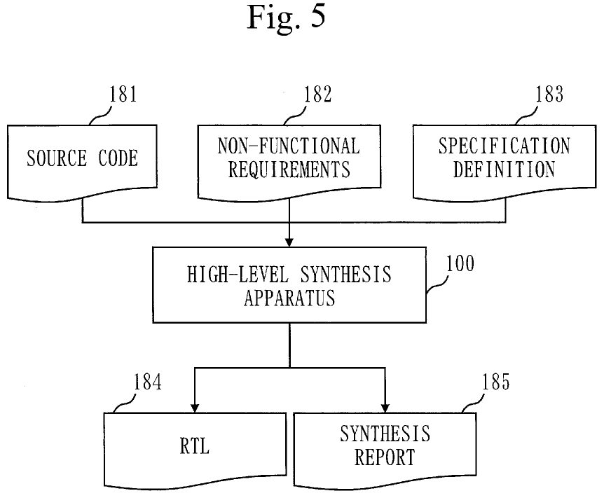

Referring to FIG. 5, input and output of the high-level synthesis apparatus 100 according to this embodiment will be described.

The high-level synthesis apparatus 100 performs a high-level synthesis process on source code 181, which is a behavioral description that describes operation of a circuit, and outputs RTL 184, which is hardware description language that causes the circuit to operate. Specifically, the high-level synthesis apparatus 100 performs the high-level synthesis process using as input the source code 181, non-functional requirements 182, and specification definitions 183, and outputs the RTL 184 and a synthesis report 185.

The source code 181 is a behavioral description that describes operation of a circuit on which high-level synthesis is to be performed, written in a high-level language such as the C language, the C++ language, the SystemC language, or the Matlab language. The source code 181 is input from the input device via the input interface 930 and stored in the storage unit 180. The source code 181 is an example of the behavioral description that describes the operation of the circuit.

The non-functional requirements 182 define non-functional requirements of the circuit that are required. Specifically, the non-functional requirements 182 define information such as the latency, area, throughput, power consumption, memory usage, and multiplier usage of the circuit that are required, and also the period for filling the circuit with input data. The non-functional requirements 182 are input from the input device via the input interface 930 and stored in the storage unit 180. The non-functional requirements of the circuit are an example of circuit characteristics that represent characteristics and performance of the circuit.

The specification definitions 183 define specifications of the circuit. Specifically, the specification definitions 183 define information such as a definition of an interface to the outside, a name of a device to be mapped, and a frequency. Specifically, the name of the device to be mapped is a model name of a field-programmable gate array (FPGA) or a process name of an application specific integrated circuit (ASIC). The specification definitions 183 are input from the input device via the input interface 930 and stored in the storage unit 180.

The RTL 184 is an example of hardware description language, that is, HDL.

The synthesis report 185 is output together with the RTL 184 from a high-level synthesis tool. In the synthesis report 185, non-functional requirements of the generated RTL 184 are set. That is, information that is set in the synthesis report 185 includes the latency, area, throughput, power consumption, memory usage, and multiplier usage of the generated RTL, and also the period for filling the circuit with input data.

*** Description of Functions ***

The logic decision unit 110 obtains the source code 181, which is a behavioral description including a plurality of execution units, and determines a circuit configuration of the entire circuit that satisfies the non-functional requirements 182 as a determined circuit configuration. The logic decision unit 110 is also referred to as a logic architecture decision unit. The source code 181 includes loop descriptions, functions, operation units, or sub modules as a plurality of execution units. This embodiment will be described using mainly functions as the execution units.

The buffer decision unit 120 determines a buffer configuration for connecting functions in the determined circuit configuration. The buffer decision unit 120 is also referred to as an internal buffer architecture decision unit.

Determining the circuit configuration of the circuit that satisfies the non-functional requirements 182, the functions that constitute this circuit, and the buffer configuration for connecting the functions, as described above, is also referred to as exploring the circuit configuration.

The code conversion unit 130 converts the source code 181 and sets high-level synthesis options so that the circuit characteristics of the determined circuit configuration satisfy threshold values.

The high-level synthesis unit 140 performs a high-level synthesis process. The high-level synthesis unit 140 performs the high-level synthesis process on the source code 181 so that the circuit configuration becomes the determined circuit configuration, using the source code 181 converted by the code conversion unit 130 and the high-level synthesis options set by the code conversion unit 130.

*** Description of Operation ***

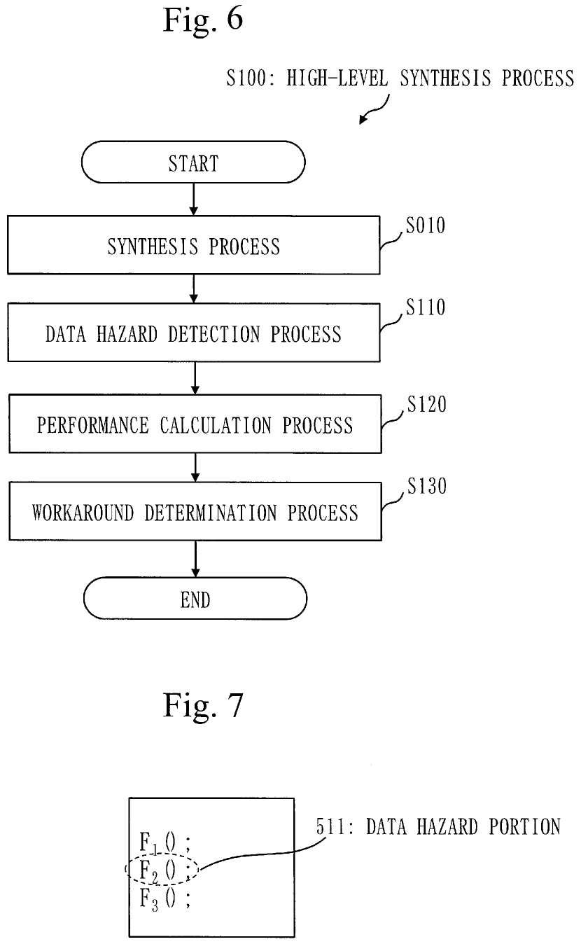

Referring to FIG. 6, a high-level synthesis process S100 by the high-level synthesis process 100 according to this embodiment will be described.

The high-level synthesis process S100 includes a synthesis process S010, a data hazard detection process S110, a performance calculation process S120, and a workaround determination process S130.

FIG. 7 illustrates a sample example of the source code 181 according to this embodiment. This embodiment will be described below using the source code 181 of FIG. 7.

<Synthesis Process S010: First Synthesis Trial>

The following information is output by the logic decision unit 110, the buffer decision unit 120, the code conversion unit 130, and the high-level synthesis unit 140. Logic architecture information, estimated latency values of each function, a high-level synthesis frequency, and a high-level synthesis log as a result of performing high-level synthesis are output. The high-level synthesis log includes circuit scale information such as the number of registers, the number of multiplexers, the number of each type of arithmetic units used, and data hazard information. The logic architecture information indicates a logic architecture of the circuit. There are a serial type and a parallel type as the logic architecture.

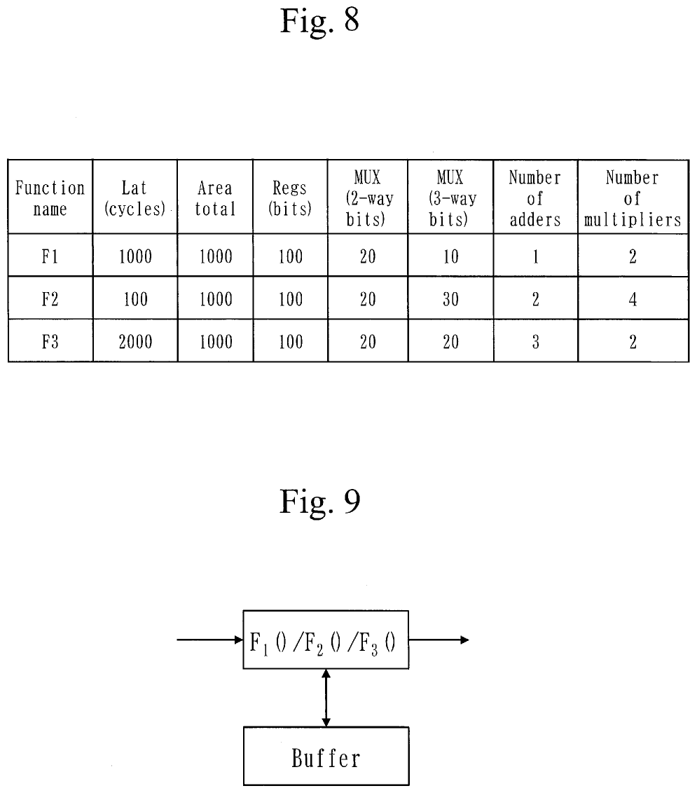

FIG. 8 is a diagram illustrating estimated latency values and circuit scale information of each function obtained from the sample example of the source code 181 in FIG. 7. The logic architecture information is supposed to be one of the serial type and the parallel type. In this embodiment, however, a case in which each of the serial type and the parallel type is output will be described. For simplicity, the estimated latency values of each function and the high-level synthesis frequency are the same in both the logic architectures.

The circuit scale information will be described further. The overall circuit scale is the total value of circuit scales of registers, multiplexers, and function units, which are operations such as four arithmetic operations. The circuit scale of registers is (circuit scale of 1-bit register)*(number of register bits). The circuit scale of multiplexers is expressed by Σ(circuit scale of N ways of 1 bit*number of bits) based on a selected number of ways, such as 2 ways, 3 ways, and N ways, of a 1-bit multiplexer. The circuit scale of function units is calculated by multiplying the circuit scale of N bits of each type of circuit, such as an adder and a multiplier, by the number of used circuits of each type and then obtaining the sum of the circuit scales of each type of circuit.

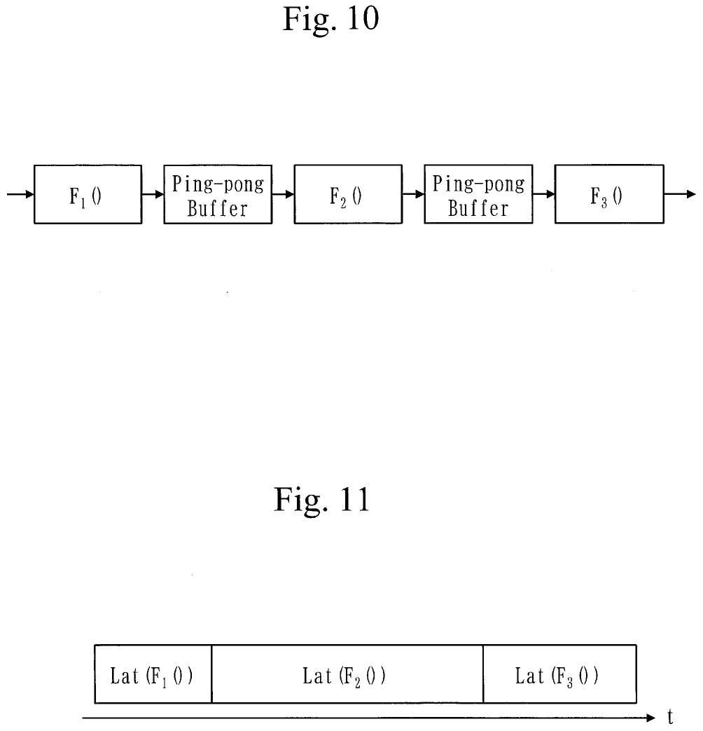

FIG. 9 is a diagram illustrating an example of the circuit configuration of the serial type. FIG. 10 is a diagram illustrating an example of the circuit configuration of the parallel type.

The serial type is the circuit configuration in which a buffer is shared by each process and processing is performed in a time-sharing manner, as illustrated in FIG. 9. The parallel type is the circuit in which each process is arranged as a pipeline stage and a buffer such as a ping-pong buffer is inserted between each process and another process, as illustrated in FIG. 10.

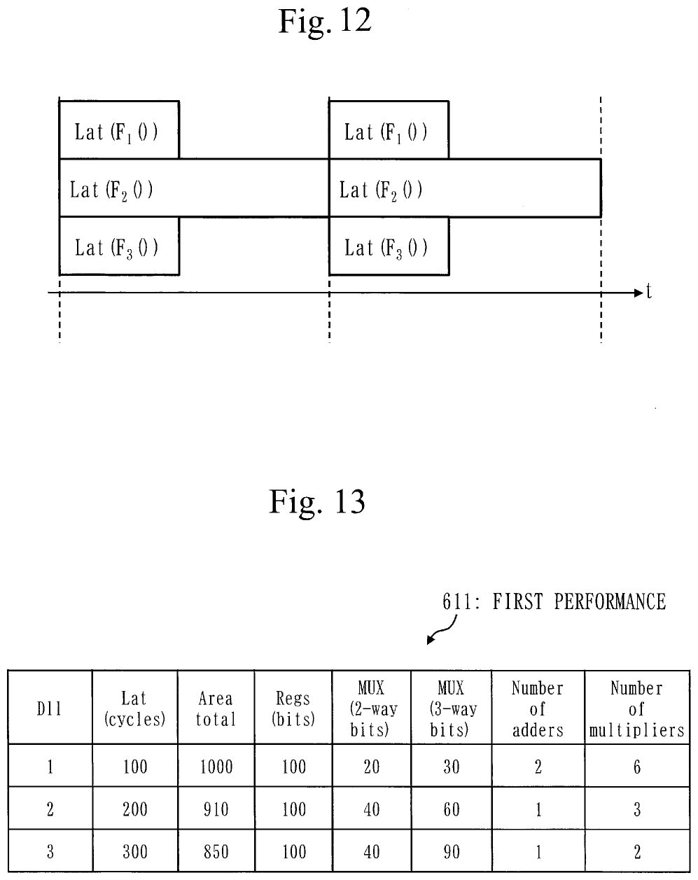

FIG. 11 is a diagram illustrating an example of the flow of processing of the serial type on a time axis. FIG. 12 is a diagram illustrating an example of the flow of processing of the parallel type on a time axis.

<Data Hazard Detection Process S110>

The data hazard detection unit 150 will be described.

The data hazard detection unit 150 detects, as a data hazard portion 511, a portion of the behavior description in which a data hazard has occurred. Specifically, the data hazard detection unit 150 extracts a log entry in which a data hazard has occurred from the high-level synthesis log and identifies the data hazard portion 511. Then, the data hazard detection unit 150 transmits critical path information that coincides with a frequency at which the data hazard does not occur. As illustrated in FIG. 7, this embodiment is described assuming that a F₂ function is the data hazard portion 511.

<Performance Calculation Process S120>

The performance calculation unit 160 will now be described. The performance calculation unit 160 is also referred to as a circuit performance calculation unit.

The performance calculation unit 160 calculates first performance 611 including the latency and circuit scale of the data hazard portion 511 when the method of reducing the pipeline performance of the circuit is applied to the data hazard portion 511. The performance calculation unit 160 also calculates second performance 612 including the latency and circuit scale of the data hazard portion when the method of reducing the operating frequency of the data hazard portion 511 is applied. Then, the performance calculation unit 160 outputs the first performance 611 and the second performance 612 as estimated performance values 610.

Specifically, the performance calculation unit 160 has a function of calculating an estimated value of the circuit performance by varying DII according to the method of reducing the pipeline performance of the circuit, with regard to the data hazard portion. The performance calculation unit 160 also has a function of calculating an estimated value of the circuit performance by reducing the operating frequency according to the method of reducing the operating frequency. Each of these functions is implemented independently. However, as will be described later, these two functions may be combined. A case in which each of the functions operates independently will be described hereinafter. The circuit performance here is the latency and circuit scale.

The circuit performance calculated by varying DII with regard to the data hazard portion is an example of the first performance 611. The circuit performance calculated by reducing the operating frequency with regard to the data hazard portion is an example of the second performance 612.

FIG. 13 is an example of the first performance 611 calculated by varying DII according to the method of reducing the pipeline performance of the circuit.

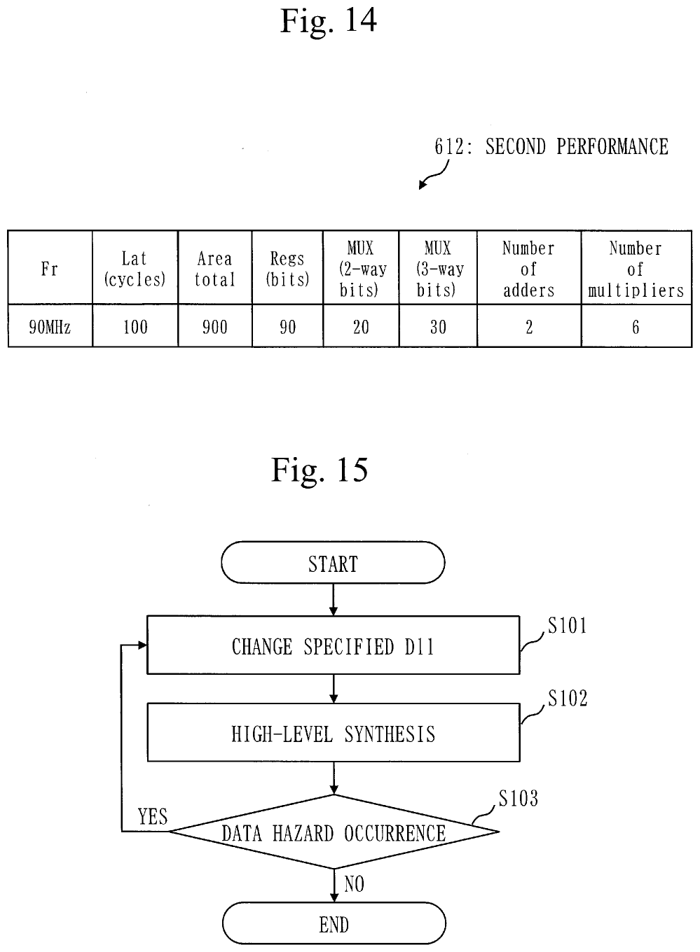

FIG. 14 is an example of the second performance 612 calculated by reducing the operating frequency according to the method of reducing the operating frequency.

The function of calculating the circuit performance by varying DII calculates a DII value and an estimated value of the latency when synthesis is performed with that DII. The latency value is calculated as indicated by Formula 1 below.

DII*Lat(Fₙ( )) (Formula 1):

In this embodiment, the data hazard has occurred in F₂, so that Fₙ==F₂ in the above Formula 1. The DII value is calculated by incrementing an incremented value up to the upper limit of any given value with respect to the DII that is set at the occurrence of the data hazard, which is the input, such as 2 incremented from 1. This given value may be set from the outside. The given value is assumed to be 3 here. The DII set at the occurrence of the data hazard, which is the input, is assumed to be 1.

Next, a method for estimating the circuit scale with each DII value will be described. Compared with DII=1, DII=2 causes operation to be performed once in every two cycles, thereby allowing circuit sharing. The circuit scale is estimated assuming that, as a synthesis result with DII=1, a value obtained by dividing the number of used arithmetic units by the DII value is the number of used arithmetic units. That is, Formula 2 below is calculated for each type of arithmetic unit, and the sum of calculated values is obtained.

Circuit scale of an arithmetic unit*number of used units/DII (Formula 2):

As a specific example, if six multipliers and two adders are used when DII=1, “circuit scale of a multiplier*6/2”+“circuit scale of an adder*2/2” applies when DII=2. That is, three multipliers and one adder are used when DII=2.

Furthermore, a multiplexer expands by circuit sharing. Therefore, the circuit scale of a multiplexer is multiplied by the DII value.

Registers remain the same.

The first performance 611 of FIG. 13 is output using the function of calculating the circuit performance by varying DII as described above.

Based on the critical path information transmitted from the data hazard detection unit, the function of calculating the circuit performance by reducing the operating frequency uses a frequency that resolves this critical path as a data hazard resolving frequency. That is, the critical path information is output from the data hazard detection unit together with the data hazard portion, and the data hazard resolving frequency is obtained based on that information. This data hazard resolving frequency is denoted as F_after. The frequency at which the data hazard has occurred is denoted as F_hazard.

In this case, the relationship F_after <F_hazard holds.

In the circuit scale after the frequency is reduced, only the number of registers changes. The circuit scale of registers is calculated by multiplying the circuit scale that is simply an input synthesis result by F_after/F_hazard.

Specifically, in the case of the sample example of the source code 181 in FIG. 7, it is assumed that 100 MHz is the input and the hazard is avoided at 90 MHz. That is, F_hazard is 100 MHz and F_after is 90 MHz. Therefore, the circuit scale after the frequency is reduced is 90/100*(1000).

FIG. 14 is a diagram illustrating a processing result when the operating frequency is reduced. In FIG. 14, DII=1 with which the data hazard has occurred is also indicated for reference.

As described above, by estimating the circuit performance, information about the circuit performance, that is, the first performance 611 and the second performance 612 can be obtained without performing high-level synthesis every time. Therefore, information about the circuit performance can be obtained in a short time.

The performance calculation unit 160 may cause the function of calculating the circuit performance by varying DII and the function of calculating the circuit performance by reducing the operating frequency to be coordinated with the high-level synthesis unit so as to perform calculations with regard to the data hazard portion.

FIG. 15 is a flowchart in a case in which the function of calculating the circuit performance by varying DII and the high-level synthesis unit are coordinated.

The performance calculation unit 160 causes the high-level synthesis unit 140 to perform the high-level synthesis process by incrementing the number of cycles. Then, the performance calculation unit 160 repeats the high-level synthesis process after incrementing the number of cycles until the data hazard in the data hazard portion is resolved. A specific process will be described below.

In step S101, the performance calculation unit 160 changes the specified DII. The performance calculation unit 160 changes the specified DII with regard to the data hazard portion. The DII is set to an incremented value with respect to the DII set at the occurrence of the data hazard, such as 2 incremented from 1.

In step S102, the performance calculation unit 160 re-performs high-level synthesis with the changed DII, and causes a high-level synthesis log to be output.

If a data hazard occurs again, the process returns to step S101, the specified DII is changed again, and the process is repeated until there is no longer any data hazard.

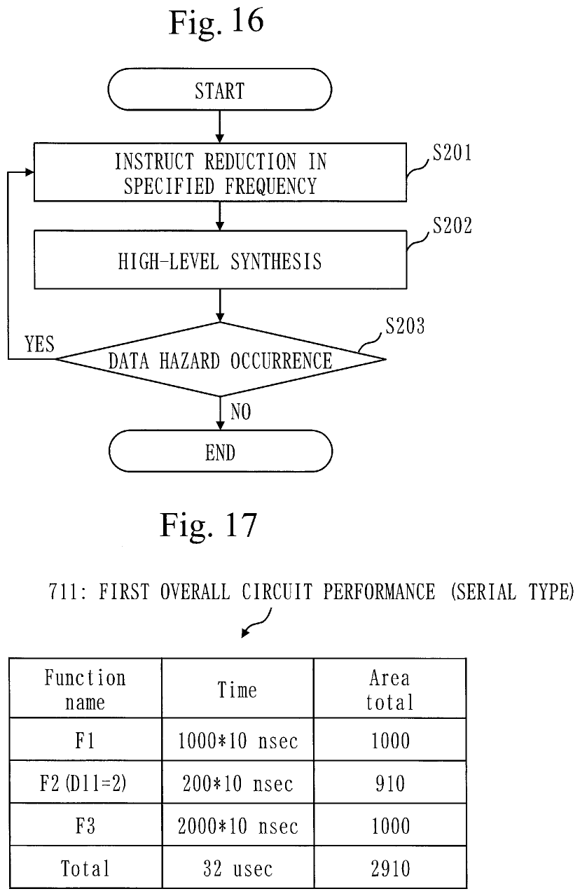

FIG. 16 is a flowchart in a case in which the function of calculating the circuit performance by reducing the operating frequency and the high-level synthesis unit are coordinated.

The performance calculation unit 160 causes the high-level synthesis unit 140 to perform the high-level synthesis process by reducing the operating frequency of the data hazard portion. Then, the performance calculation unit 160 repeats the high-level synthesis process after reducing the operating frequency until the data hazard in the data hazard portion is resolved.

In step S201, the performance calculation unit 160 instructs reduction in the operating frequency. The performance calculation unit 160 sets the operating frequency of the data hazard portion to a value obtained by subtracting only a specified reduction value from the setting value of the operating frequency for high-level synthesis set for the data hazard portion, which is the input. As a specific example, when the operating frequency at which the initial data hazard has occurred is 100 MHz and the specified reduction value is 10 MHz, 90 MHz (100 MHz−10 MHz) is specified.

In step S202, the performance calculation unit 160 performs high-level synthesis at the changed frequency, and causes a high-level synthesis log to be output.

If a data hazard occurs again, the performance calculation unit 160 returns to step S101, re-instructs reduction in the operating frequency, and repeats the process until there is no longer any data hazard.

By using high-level synthesis results as illustrated in FIGS. 15 and 16, the latency and circuit scale can be estimated more accurately.

The performance calculation unit 160 may combine the function of calculating the circuit performance by varying DII and the function of calculating the circuit performance by reducing the operating frequency.

That is, the performance calculation unit 160 causes the high-level synthesis unit 140 to perform the high-level synthesis by incrementing the number of cycles and reducing the operating frequency of the data hazard portion. Then, the performance calculation unit 160 repeats the high-level synthesis process after incrementing the number of cycles and reducing the operating frequency of the data hazard portion until the data hazard in the data hazard portion is resolved. In this way, the performance calculation unit 160 may calculate the estimated performance values 610 by varying both the DII and operating frequency conditions.

The performance calculation unit 160 outputs the calculated estimated performance values 610 to the workaround determination unit 170.

<Workaround Determination Process S130>

The operation of the workaround determination unit 170 will now be described. As described above, the operation of the workaround determination unit 170 in the case in which a data hazard has occurred in the F₂ function in the source code 181 of FIG. 7 will be described. The workaround determination unit 170 is also referred to as a data hazard workaround determination unit.

The workaround determination unit 170 determines a workaround that resolves the data hazard in the data hazard portion based on the estimated performance values 610. The workaround determination unit 170 determines, as the workaround, one of the method of reducing the pipeline performance of the circuit, the method of reducing the operating frequency of the data hazard portion, and a method composed of a combination of the method of reducing the pipeline performance of the circuit and the method of reducing the operating frequency of the data hazard portion.

The estimated performance values 610 are estimated values of the circuit performance including the latency and circuit scale of the circuit. As described above, the estimated performance values 610 include the first performance 611 and the second performance 612.

The workaround determination unit 170 calculates first overall circuit performance 711 including the latency and circuit scale of the entire circuit when the method of reducing the pipeline performance of the circuit is applied to the data hazard portion based on the first performance 611. The workaround determination unit 170 also calculates second overall circuit performance 712 including the latency and circuit scale of the entire circuit when the method of reducing the operating frequency of the data hazard portion is applied. Then, the workaround determination unit 170 determines a workaround based on the first overall circuit performance 711 and the second overall circuit performance 712.

Lastly, the workaround determination unit 170 implements the workaround, and causes the high-level synthesis unit 140 to re-perform the high-level synthesis process.

That is, the workaround determination unit 170 is a functional unit that selects the workaround using the DII value or the workaround using the frequency setting, based on the circuit performance of the portion in which the data hazard has occurred and the logic architecture information from the logic architecture, and performs overall re-synthesis. The circuit performance of the portion in which the data hazard has occurred is the circuit performance of the portion in which the data hazard has occurred when DII is varied, when the frequency is reduced, or when a combination of these are implemented.

The workaround determination unit 170 selects a method for determining the workaround based on the logic architecture information indicating whether the circuit is the serial type or the parallel type. The method for determining the workaround varies depending on whether the logic architecture of the circuit is the serial type or the parallel type, so that the serial type and the parallel type will be described separately.

The process when the serial type is input as the logic architecture will be described. First, a formula for calculating processing time reflecting the specified DII in the serial type based on the latency output from the performance calculation unit 160 is (Formula 3).

ΣLat(Fₙ( ))/Fr (Formula 3):

Note that Fr is the frequency.

Based on the latency of each function other than the F₂ function in FIG. 8 and the latency of each function other than the F₂ function when DII=2 as indicated in FIG. 13, (1000+200+2000)/100 MHz=3200*5 nsec is calculated. Similarly, when DII=3, (1000+200+2000)/100 MHz=3300*5 nsec is calculated.

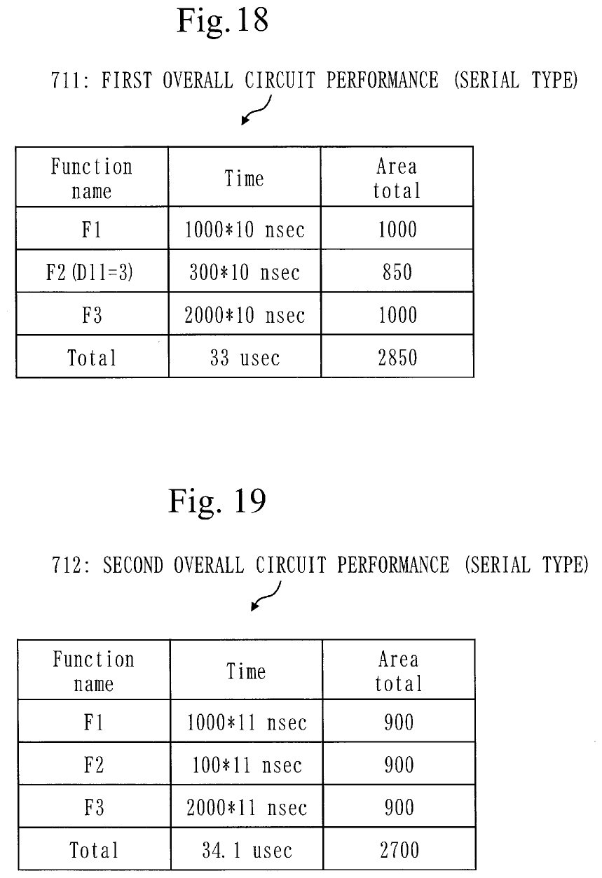

The sum of circuit scales is also calculated. FIGS. 17 and 18 illustrate results obtained by the above calculations.

FIG. 17 is a diagram illustrating the overall circuit scale and performance, that is, the first overall circuit performance 711 when DII=2. FIG. 18 is a diagram illustrating the overall circuit scale and performance, that is, the first overall circuit performance 711 when DII=3.

When the frequency is reduced in the serial type, it is necessary to set the same frequency as the frequency of the function in which the data hazard has occurred also for the functions in which no data hazard has occurred. This is because with the serial type it is not possible to perform synthesis by varying only the frequency of a portion of the circuit in which the data hazard has occurred. Therefore, when the frequency is reduced, the overall latency is calculated as indicated in (Formula 4) below.

F_after*(ΣLat(Fₙ( ))+Lat(Fₘ( )) (Formula 4):

Note that Fₘ is the function in which the data hazard has occurred, and F is the function in which no data hazard has occurred.

With regard to the circuit scale of Fₙ, only the number of registers changes as described above. The circuit scale of the registers is calculated by multiplying the circuit scale that is simply an input synthesis result by F_after/F_hazard.

FIG. 19 is a diagram illustrating the circuit scale and performance of each function, that is, the second overall circuit performance 712 when the frequency is reduced.

As described above, in the case of the serial type, the workaround determination unit 170 calculates the processing performance of the entire circuit separately by varying the DII and by reducing the frequency, and selects one with the shortest processing time. In the examples in FIGS. 17 to 19, the workaround determination unit 170 selects DII=2 with 32 usec. That is, the workaround determination unit 170 determines the method of setting DII=2 for the data hazard portion 511 as the workaround.

The workaround determination unit 170 may output the determined workaround via the output interface 940 to the outside of the high-level synthesis apparatus 100. A user may assess the workaround output to the outside and determine the workaround to be adopted.

Alternatively, in the high-level synthesis apparatus 100, which of the processing time and the circuit scale has priority may be set in advance as priority information. The workaround determination unit 170 determines which of the processing time and the circuit scale has priority in accordance with the priority information. As a specific example, when the circuit scale has priority, the workaround determination unit 170 selects the reduction in frequency that results in an area total of 2700 in the examples in FIGS. 17 to 19.

Next, the process when the parallel type is input as the logic architecture will be described.

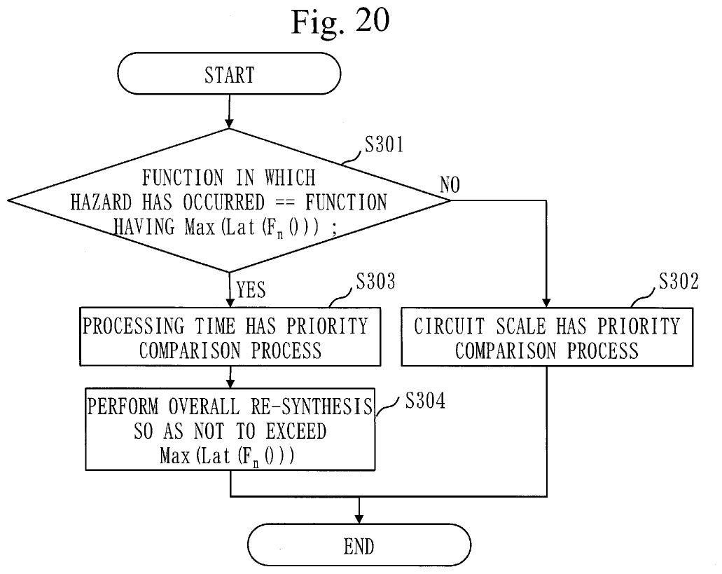

FIG. 20 is a flowchart of the workaround determination process when the parallel type is input.

In step S301, the workaround determination unit 170 determines whether the function in which the data hazard has occurred coincides with F having Max(LatFₙ( )), which determines the latency in the parallel type.

If F having Max(LatFₙ( )) does not coincide with the function in which the data hazard has occurred, the process proceeds to step S302. If F having Max(LatFₙ( )) coincides with the function in which the data hazard has occurred, the process proceeds to step S303.

The function in which the data hazard has occurred does not affect the overall latency performance if the latency of the function does not exceed Max(LatFₙ( )). Therefore, in step S302, the workaround determination unit 170 selects a workaround that results in the smallest circuit scale from DII, reduction in frequency, and a combination of these.

In the specific examples, FIG. 19 indicates that Max(LatFₙ( )) is F₃. However, the function in which the data hazard has occurred is F₂. Therefore, the latency of the function in which the data hazard has occurred does not exceed Max(LatFₙ( )). Based on the results in FIGS. 13 and 14, the circuit scale is smallest when DII=3. In addition, the latency of F₂ when DII=3 does not exceed Max(LatFₙ( )).

In this way, the circuit scale can be reduced while maintaining the overall processing time even when a data hazard has occurred.

When Fₙ having Max(LatFₙ( )) coincides with the function with the data hazard has occurred, a portion of the circuit in which the data hazard has occurred determines the overall processing time in the parallel type. Therefore, in step S303, the workaround determination unit 170 gives priority to the processing time, and compares DII, reduction in frequency, and a combination of these to determine which one results in the shortest processing time. Then, the workaround determination unit 170 selects the workaround that results in the shortest processing time.

In step S304, the workaround determination unit 170 performs overall re-synthesis so that the processing time of the functions other than the function in which the data hazard has occurred is within the determined shortest processing time. The shortest processing time determined in step S303 is the overall processing time of the parallel type as a whole. For this reason, there is no problem for the other functions in which no data hazard has occurred as long as the processing time is shorter than the determined shortest processing time. In other words, for the other functions in which no data hazard has occurred, there is no problem in increasing the processing time as long as the determined shortest processing time is not exceeded. Therefore, overall re-synthesis is performed so that the processing time of the functions other than the function in which the data hazard has occurred is within the determined shortest processing time.

A different sample will be defined for the purpose of explanation, although this sample does not satisfy the above condition and is thus not supposed to be implemented. The following will be described assuming that the function in which a data hazard has occurred is F₃ instead of F₂.

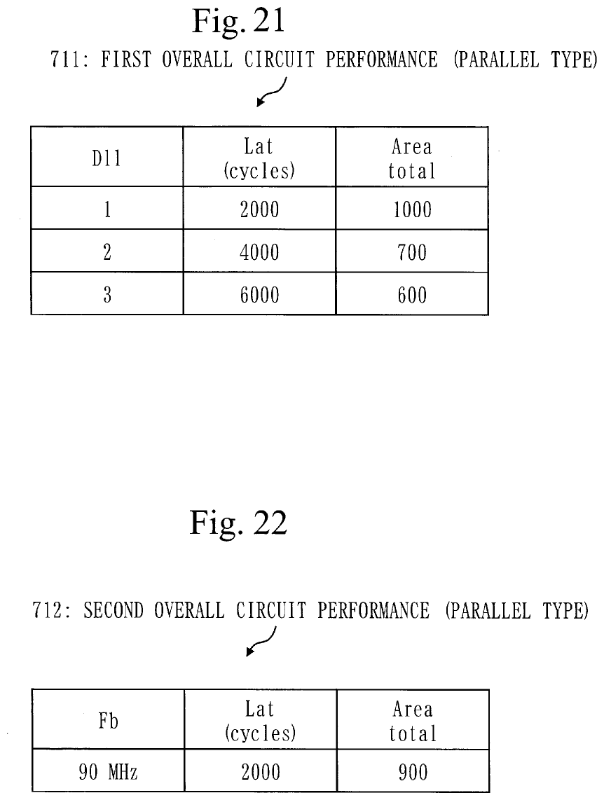

FIG. 21 is a diagram representing an example of the latency and circuit scale when DII is varied, that is, the first overall circuit performance 711 in the case in which the F₃ function is the function in which the data hazard has occurred.

FIG. 22 is a diagram representing an example of the latency and circuit scale when the frequency is reduced, that is, the second overall circuit performance 712 in the case in which the F₃ function is the function in which the data hazard has occurred.

When F₃ is the function in which the data hazard has occurred, F having Max(LatFₙ( )) coincides with the function in which the data hazard has occurred, as indicated in FIG. 19.

FIGS. 21 and 22 indicate 4000/100 MHz=40 usec with DII=2 and 2000/90 MHz=22 usec with 90 MHz. Therefore, the result indicating that the method of reducing the operating frequency has the shortest processing time is obtained. That is, 22 usec determines the performance of the entire circuit. It is assumed here that a data hazard occurs with DII=1. Therefore, as the workaround for the data hazard, one of the method of DII=2 and the method of reducing the operating frequency to 90 MHz is selected. The method of reducing the operating frequency to 90 MHz is selected here.

Then, the workaround determination unit 170 implements circuit sharing in each of the functions F₁ and F₂ in which no data hazard has occurred within the upper-limit processing time of 22 usec so as to reduce the circuit scale.

In this way, the circuit scale can be reduced, although the data hazard has occurred and the latency increases.

As described above, the workaround determination unit 170 can obtain the optimal hardware description language for the entire circuit by instructing the high-level synthesis unit to re-perform high-level synthesis by the workaround that is the determined method for avoiding the data hazard and also on the functions in which no data hazard has occurred.

*** Other Configurations ***

<First Variation>

The high-level synthesis apparatus 100 may include a communication device that communicates with other devices via a network. The communication device has a receiver and a transmitter. The communication device is connected wirelessly to a communication network such as a LAN, the Internet, or a telephone line. Specifically, the communication device is a communication chip or a network interface card (NIC). The high-level synthesis apparatus 100 may obtain source code, non-functional requirements, or definitions to be used via the communication device. The high-level synthesis apparatus 100 may also display RTL or a synthesis report on an external display device via the communication device.

<Second Variation>

In this embodiment, the functions of the logic decision unit 110, the buffer decision unit 120, the code conversion unit 130, the high-level synthesis unit 140, the data hazard detection unit 150, the performance calculation unit 160, and the workaround determination unit 170 are realized by software. As a variation, the functions of the logic decision unit 110, the buffer decision unit 120, the code conversion unit 130, the high-level synthesis unit 140, the data hazard detection unit 150, the performance calculation unit 160, and the workaround determination unit 170 may be realized by hardware.

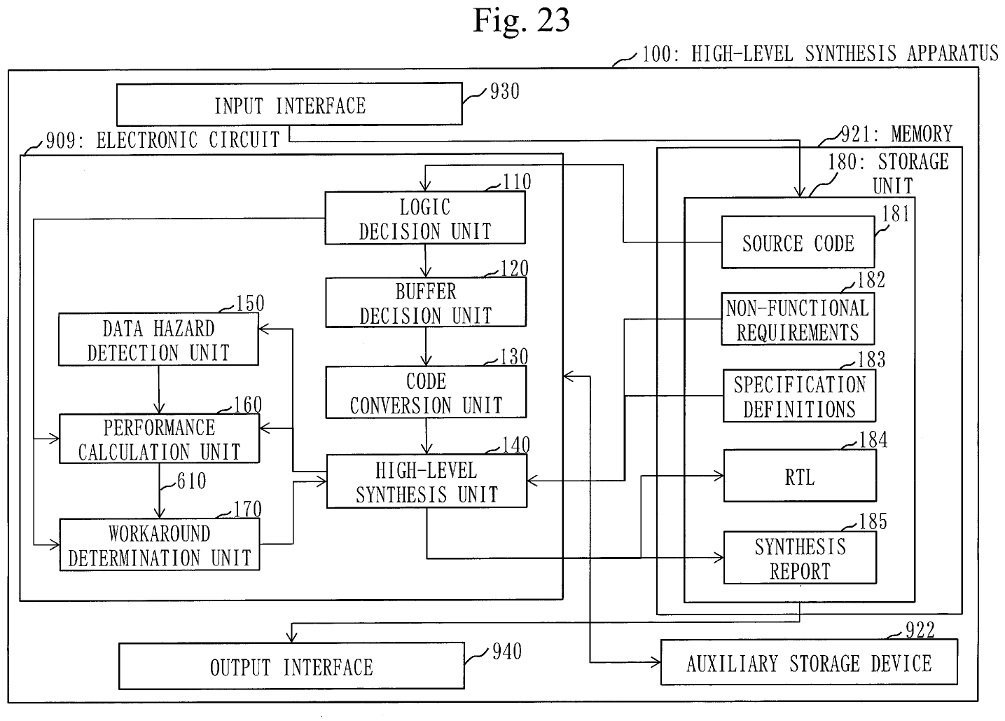

FIG. 23 is a diagram illustrating a configuration of the high-level synthesis apparatus 100 according to one variation of this embodiment.

The high-level synthesis apparatus 100 includes an electronic circuit 909, the memory 921, the auxiliary storage device 922, the input interface 930, and the output interface 940.

The electronic circuit 909 is a dedicated circuit that realizes the functions of the logic decision unit 110, the buffer decision unit 120, the code conversion unit 130, the high-level synthesis unit 140, the data hazard detection unit 150, the performance calculation unit 160, and the workaround determination unit 170.

Specifically, the electronic circuit 909 is a single circuit, a composite circuit, a programmed processor, a parallel-programmed processor, a logic IC, a GA, an ASIC, or an FPGA. GA is an abbreviation for Gate Array.

The functions of the logic decision unit 110, the buffer decision unit 120, the code conversion unit 130, the high-level synthesis unit 140, the data hazard detection unit 150, the performance calculation unit 160, and the workaround determination unit 170 may be realized by one electronic circuit, or may be distributed among and realized by a plurality of electronic circuits.

As another variation, some of the functions of the logic decision unit 110, the buffer decision unit 120, the code conversion unit 130, the high-level synthesis unit 140, the data hazard detection unit 150, the performance calculation unit 160, and the workaround determination unit 170 may be realized by the electronic circuit, and the rest of the functions may be realized by software.

Each of the processor and the electronic circuit is also referred to as processing circuitry. That is, in the high-level synthesis apparatus 100, the functions of the logic decision unit 110, the buffer decision unit 120, the code conversion unit 130, the high-level synthesis unit 140, the data hazard detection unit 150, the performance calculation unit 160, and the workaround determination unit 170 are realized by the processing circuitry.

### Description of Effects of this Embodiment

The high-level synthesis apparatus 100 according to this embodiment performs a high-level synthesis or behavioral synthesis process using a behavioral description as input, and outputs an HDL description. The performance calculation unit calculates latency performance and circuit scale performance based on a change in circuit performance information or a pipeline configuration at occurrence of a data hazard.

The workaround determination unit determines one of the method of reducing the pipeline performance and the method of reducing the operating frequency, or determines a combination of the both methods, for the data hazard portion, in order to resolve the data hazard. The workaround determination unit determines the method for resolving the data hazard based on the latency and circuit scale of the entire circuit including portions other than a portion in which the data hazard has occurred. Therefore, the high-level synthesis apparatus 100 according to this embodiment can automatically implement a workaround for occurrence of a data hazard, which has been conventionally implemented manually. Furthermore, an optimal circuit can be designed in a short time without depending on a designer.

In the high-level synthesis apparatus 100 according to this embodiment, the workaround determination unit explores latency and circuit scale for portions of the circuit with no data hazard, based on results of varying the pipeline configuration or varying the frequency in the portion of the circuit in which the data hazard has occurred, and re-performs high-level synthesis. Therefore, the high-level synthesis apparatus 100 according to this embodiment can obtain optimal hardware description language for the entire circuit.

In the first embodiment above, each unit of the high-level synthesis apparatus is described as an independent functional block. However, the configuration of the high-level synthesis apparatus may be different from the configurations described in the above embodiment. The functional blocks of the high-level synthesis apparatus may be implemented in any configuration, provided that the functions described in the above embodiment can be realized. The high-level synthesis apparatus may be a system composed of a plurality of apparatuses instead of one apparatus.

A plurality of portions of the first embodiment may be implemented in combination. Alternatively, one portion of this embodiment may be partially implemented. Alternatively, this embodiment may be implemented as a whole or partially in any combination.

That is, in the first embodiment, it is possible to freely combine each embodiment, modify any constituent element of each embodiment, or omit any constituent element in each embodiment.

The embodiment described above is an essentially preferable example, and is not intended to limit the scope of the present invention, the scope of applications of the present invention, and the scope of intended uses of the present invention. The embodiment described above can be modified in various ways as needed.

### REFERENCE SIGNS LIST

100: high-level synthesis apparatus, 110: logic decision unit, 120: buffer decision unit, 130: code conversion unit, 140: high-level synthesis unit, 150: data hazard detection unit, 511: data hazard portion, 160: performance calculation unit, 610: estimated performance values, 611: first performance, 612: second performance, 170: workaround determination unit, 711: first overall circuit performance, 712: second overall circuit performance, 180: storage unit, 181: source code, 182: non-functional requirements, 183: specification definitions, 184: RTL, 185: synthesis report, 909: electronic circuit, 910: processor, 921: memory, 922: auxiliary storage device, 930: input interface, 940: output interface, S100: high-level synthesis process, S010: synthesis process, S110: data hazard detection process, S120: performance calculation process, S130: workaround determination process

1. A high-level synthesis apparatus to perform a high-level synthesis process on a behavioral description that describes operation of a circuit, and output hardware description language that causes the circuit to operate, the high-level synthesis apparatus comprising:
processing circuitry to:
detect, as a data hazard portion, a portion of the behavioral description in which a data hazard has occurred; and
determine, as a workaround to resolve the data hazard in the data hazard portion, one of a method of reducing pipeline performance of the circuit, a method of reducing operating frequency of the data hazard portion, and a method composed of a combination of the method of reducing the pipeline performance of the circuit and the method of reducing the operating frequency of the data hazard portion, based on estimated performance values which are estimated values of circuit performance including latency and circuit scale of the circuit.

2. The high-level synthesis apparatus according to claim 1,
wherein the processing circuitry calculates first performance including latency and circuit scale of the data hazard portion when the method of reducing the pipeline performance of the circuit is applied to the data hazard portion, calculates second performance including latency and circuit scale of the data hazard portion when the method of reducing the operating frequency of the data hazard portion is applied, and outputs the first performance and the second performance as the estimated performance values, and
determines the workaround based on the estimated performance values.

3. The high-level synthesis apparatus according to claim 2,
wherein the method of reducing the pipeline performance of the circuit is a method of increasing the number of cycles for processing the data hazard portion in the behavioral description once, and
wherein the processing circuitry,
performs the high-level synthesis process by incrementing the number of cycles, and repeats the high-level synthesis process after incrementing the number of cycles until the data hazard in the data hazard portion is resolved.

4. The high-level synthesis apparatus according to claim 2,
wherein the processing circuitry performs the high-level synthesis process by reducing the operating frequency of the data hazard portion, and repeats the high-level synthesis process after reducing the operating frequency of the data hazard portion until the data hazard in the data hazard portion is resolved.

5. The high-level synthesis apparatus according to claim 2,
wherein the method of reducing the pipeline performance of the circuit is a method of increasing the number of cycles for processing the data hazard portion in the behavioral description once, and
wherein the processing circuitry performs the high-level synthesis process by incrementing the number of cycles and reducing the operating frequency of the data hazard portion, and repeats the high-level synthesis process after incrementing the number of cycles and reducing the operating frequency of the data hazard portion until the data hazard in the data hazard portion is resolved.

6. The high-level synthesis apparatus according to claim 3,
wherein the processing circuitry calculates first overall circuit performance including latency and circuit scale of entirety of the circuit when the method of reducing the pipeline performance of the circuit is applied to the data hazard portion based on the first performance, calculates second overall performance including latency and circuit scale of the entirety of the circuit when the method of reducing the operating frequency of the data hazard portion is applied, and determines the workaround based on the first overall circuit performance and the second overall circuit performance.

7. The high-level synthesis apparatus according to claim 3,
wherein the processing circuitry selects a method for determining the workaround based on logic architecture information that indicates whether the circuit is a serial type or a parallel type.

8. The high-level synthesis apparatus according to claim 3,
wherein the processing circuitry implements the workaround, and re-performs the high-level synthesis process.

9. A high-level synthesis method of a high-level synthesis apparatus to perform a high-level synthesis process on a behavioral description that describes operation of a circuit, and output hardware description language that causes the circuit to operate, the high-level synthesis method comprising:
detecting, as a data hazard portion, a portion of the behavioral description in which a data hazard has occurred; and
determining, as a workaround to resolve the data hazard in the data hazard portion, one of a method of reducing pipeline performance of the circuit, a method of reducing operating frequency of the data hazard portion, and a method composed of a combination of the method of reducing the pipeline performance of the circuit and the method of reducing the operating frequency of the data hazard portion, based on estimated performance values which are estimated values of circuit performance including latency and circuit scale of the circuit.

10. A non-transitory computer readable medium storing a high-level synthesis program of a high-level synthesis apparatus to perform a high-level synthesis process on a behavioral description that describes operation of a circuit, and output hardware description language that causes the circuit to operate, the high-level synthesis program causing the high-level synthesis apparatus, which is a computer, to execute:
a data hazard detection process to detect, as a data hazard portion, a portion of the behavioral description in which a data hazard has occurred; and
a workaround determination process to determine, as a workaround to resolve the data hazard in the data hazard portion, one of a method of reducing pipeline performance of the circuit, a method of reducing operating frequency of the data hazard portion, and a method composed of a combination of the method of reducing the pipeline performance of the circuit and the method of reducing the operating frequency of the data hazard portion, based on estimated performance values which are estimated values of circuit performance including latency and circuit scale of the circuit.
